(19) United States
(12) Patent Application Publication
(10) Pub. No.: US 2025/0042720 A1
(43) Pub. Date: Feb. 6, 2025

(54) INTEGRATED MEMS OPTICAL SWITCH WITH PIEZOELECTRIC MEMS ACTUATORS

(71) Applicant: nEye Systems, Inc., Berkeley, CA (US)

(72) Inventors: Tae Joon SEOK, El Cerrito, CA (US); Xiaosheng ZHANG, Davis, CA (US); Ming Chiang A. WU, Piedmont, CA (US); Noriaki KANEDA, Westfield, NJ (US); Kyungmok KWON, El Cerrito, CA (US)

(21) Appl. No.: 18/791,052

(22) Filed: Jul. 31, 2024

Related U.S. Application Data
(63) Continuation of application No. 63/516,822, filed on Jul. 31, 2023.

(51) Int. Cl. B81B 3/00; G02B 6/27; G02B 6/35

(52) U.S. Cl. CPC B81B 3/0021; G02B 6/2773; G02B 6/3578; B81B 2201/032; B81B 2201/045; B81B 2207/015

(57) ABSTRACT

Photonic integrated circuits (PICs) are provided that include silicon photonic structures such as a network of horizontal and vertical bus waveguides and micro-electro-mechanical-system (MEMS) actuated switching elements configured to selectively couple light between selected horizontal and vertical bus waveguides. The PICs of the present disclosure can be applied or used in a wide variety of fields including but not limited to fiber-optic communication, photonic computing, and light detection and ranging (LiDAR). The MEMS actuated switching elements can comprise piezoelectric actuators.

### PRIORITY CLAIM

This patent application claims priority to U.S. provisional patent application No. 63/516,822, titled “INTEGRATED MEMS OPTICAL SWITCH WITH PIEZOELECTRIC MEMS ACTUATORS,” and filed on Jul. 31, 2023, which is herein incorporated by reference in its entirety.

### FIELD

The present disclosure details novel MEMS optical circuit switches.

### BACKGROUND

The emergence of data-intensive cloud computing, high-performance computing (HPC), artificial intelligence (AI) and machine learning (ML) systems has led an explosive growth of data traffics in data center networks. Conventional electrical packet switches which support optical networks in present data centers are facing increasing challenges in energy consumption as the required data rate, which is the speed of data transmission, continues to increase. Optical circuit switches require significantly lower power than typical electrical switches and, thus, can solve some of these energy challenges by offering for certain uses/applications unlimited bandwidth that is agnostic to the data rate.

Silicon photonics leveraging advanced CMOS foundry manufacturing is a viable technology platform to demonstrate large-scale optical switches. Silicon photonic devices typically employ waveguides formed in a thin silicon-on-insulator (SOI) layer, where a myriad of photonic components are routed by the waveguides to provide a complex functionality. Integrated optical switches implemented on silicon photonics platform, or “silicon photonic switches”, offer high-density integration and low-cost manufacturing.

Micro-electromechanical systems (MEMS) waveguide couplers are used in silicon photonic devices to couple selected bus waveguides to another. These MEMS waveguide couplers typically use electrostatic actuators that use the electric force between two capacitor plates to pull them together, and therefore adjust the position of the waveguide coupler. However, electrostatic actuators can suffer from pull-in instability which limits their travel ranges and reliability.

There is a need in the art for improved MEMS waveguide couplers.

### SUMMARY OF THE DISCLOSURE

A photonic integrated circuit (PIC) device is provided, comprising: a substrate; one or more rows of horizontal waveguides disposed on a first layer of the substrate; one or more columns of vertical waveguides disposed on a second layer of the substrate; one or more fiber couplers configured to couple external light to the one or more rows of horizontal waveguides or columns of vertical waveguides; and a matrix of photonic switches arranged at intersections between the one or more rows of horizontal waveguides and the one or more rows of vertical waveguides, the photonic switches including piezoelectric actuators that are selectively actuated to transfer light from the first and second horizontal waveguides for a selected row of horizontal waveguides to first and second vertical waveguides of an intersecting column of vertical waveguides.

In some aspects, each photonic switch comprises a coupler waveguide, wherein the piezoelectric actuators are disposed on the coupler waveguide.

In other aspects, the piezoelectric actuators are disposed on a first surface of the coupler waveguide.

In one aspect, the piezoelectric actuators are disposed on first and second surfaces of the coupler waveguide.

In some aspects, the coupler waveguide comprises a silicon material.

In additional aspects, application of voltage to the piezoelectric actuators induces an internal mechanical strain in the piezoelectric actuators to bend the coupler waveguide.

In some aspects, the photonic switches each comprise an OFF state in which the coupler waveguide is maintained at a distance away from the one or more rows of horizontal waveguides or vertical waveguides such that light propagating in the one or more rows of horizontal waveguides or vertical waveguides is not affected by the coupler waveguides.

In other aspects, the photonic switches each comprise an OFF state in which ends of the coupler waveguides are moved towards the one or more rows of horizontal waveguides or vertical waveguides to optically couple the one or more rows of horizontal waveguides or vertical waveguides to the coupler waveguides.

In one aspect, the PIC is fabricated on a silicon-on-insulator (SOI) substrate.

In other aspects, the one or more rows of horizontal waveguides and one or more rows of vertical waveguides are disposed on first and second layers of the SOI substrate.

In some aspects, the matrix of photonic switches are fabricated on a third layer of the SOI substrate.

In one aspect, the third layer is above the first and second layers.

In additional aspects, the one or more rows of horizontal waveguides and one or more rows of vertical waveguides are disposed on a first substrate, and the matrix of photonic switches are fabricated on a second substrate.

In another aspect, the PIC includes complementary metal-oxide-semiconductor (CMOS) driver circuits disposed on the second substrate and configured to control actuation of the matrix of photonic switches.

A photonic integrated circuit (PIC) device is also provided, comprising: a substrate; one or more rows of horizontal waveguides disposed on a first layer of the substrate, each row of horizontal waveguides comprising a first horizontal waveguide and a second horizontal waveguide; one or more columns of vertical waveguides disposed on a second layer of the substrate, each column of vertical waveguides comprising a first vertical waveguide and a second vertical waveguide; one or more fiber couplers configured to couple external light to the one or more rows of horizontal waveguides or columns of vertical waveguides; an input polarization splitter rotator (PSR) coupled to each of the one or more fiber couplers, each input PSR being configured to split the coupled light into the first and second horizontal waveguides in each of the one or more rows of horizontal waveguides or into the first and second vertical waveguides in each of the one or more columns of vertical waveguides; and a matrix of photonic switches arranged at intersections between the one or more rows of horizontal waveguides and the one or more rows of vertical waveguides, the photonic switches including piezoelectric actuators that are selectively actuated to transfer light from the first and second horizontal waveguides for a given row of horizontal waveguides to first and second vertical waveguides of an intersecting column of vertical waveguides.

In some aspects, each photonic switch comprises a coupler waveguide, wherein the piezoelectric actuators are disposed on the coupler waveguide.

In other aspects, the piezoelectric actuators are disposed on a first surface of the coupler waveguide.

In one aspect, the piezoelectric actuators are disposed on first and second surfaces of the coupler waveguide.

In some aspects, the coupler waveguide comprises a silicon material.

In additional aspects, application of voltage to the piezoelectric actuators induces an internal mechanical strain in the piezoelectric actuators to bend the coupler waveguide.

In some aspects, the photonic switches each comprise an OFF state in which the coupler waveguide is maintained at a distance away from the one or more rows of horizontal waveguides or vertical waveguides such that light propagating in the one or more rows of horizontal waveguides or vertical waveguides is not affected by the coupler waveguides.

In other aspects, the photonic switches each comprise an OFF state in which ends of the coupler waveguides are moved towards the one or more rows of horizontal waveguides or vertical waveguides to optically couple the one or more rows of horizontal waveguides or vertical waveguides to the coupler waveguides.

In one aspect, the PIC is fabricated on a silicon-on-insulator (SOI) substrate.

In other aspects, the one or more rows of horizontal waveguides and one or more rows of vertical waveguides are disposed on first and second layers of the SOI substrate.

In some aspects, the matrix of photonic switches are fabricated on a third layer of the SOI substrate.

In one aspect, the third layer is above the first and second layers.

In additional aspects, the one or more rows of horizontal waveguides and one or more rows of vertical waveguides are disposed on a first substrate, and the matrix of photonic switches are fabricated on a second substrate.

In another aspect, the PIC includes complementary metal-oxide-semiconductor (CMOS) driver circuits disposed on the second substrate and configured to control actuation of the matrix of photonic switches.

In another aspect, the PIC includes an output PSR coupled to each of the one or more columns of vertical waveguides, each output PSR being configured to combine the light from the first and second vertical waveguides into a single output waveguide.

In some aspects, the PIC includes one or more output polarization-insensitive couplers coupled to each output waveguide.

In another aspect, the input PSRs are configured to split the input light into two orthogonal polarizations in two separate waveguides and rotate a polarization of one of the two separate waveguides to achieve the same polarization in the two separate waveguides.

In additional aspects, the polarization-diverse photonic switches are micro-electro-mechanical-system (MEMS) switches.

### BRIEF DESCRIPTION OF THE DRAWINGS

The novel features of the invention are set forth with particularity in the claims that follow. A better understanding of the features and advantages of the present invention will be obtained by reference to the following detailed description that sets forth illustrative embodiments, in which the principles of the invention are utilized, and the accompanying drawings of which:

FIGS. 1A-1B show top-view schematics of the integrated MEMS optical circuit switch (OCS) with piezoelectric MEMS actuators.

FIGS. 2A-2J show the structure of bus waveguides, coupler waveguide and piezoelectric MEMS actuators in one unit cell.

FIGS. 3A-3B show front and side view schematics using the single-wafer process.

FIGS. 4A-4F shows front and side view schematics using the two-wafer process.

FIGS. 5A-5B show top-view schematics of the polarization diverse integrated MEMS OCS with piezoelectric MEMS actuators.

FIGS. 6A-6J show the structure of bus waveguides, coupler waveguides and piezoelectric MEMS actuators in one unit cell.

FIGS. 7A-7B show front and side view schematics using the single-wafer process.

FIGS. 8A-8F shows front and side view schematics using the two-wafer process.

### DETAILED DESCRIPTION

This disclosure provide systems and methods that include integrated micro-electromechanical systems (MEMS) optical switches with piezoelectric MEMS actuators. This disclosure provides novel silicon photonics chips or photonic integrated circuits (PICs) that include systems and methods for light coupling between optical fibers and silicon photonics chips (for example, MEMS optical switch chips). Generally, the PICS of the present disclosure are configured to detect, generate, transport, and/or process light. The PICS of the present disclosure can be applied or used in a wide variety of fields including but not limited to fiber-optic communication, photonic computing, and beam steering including light detection and ranging (LiDAR).

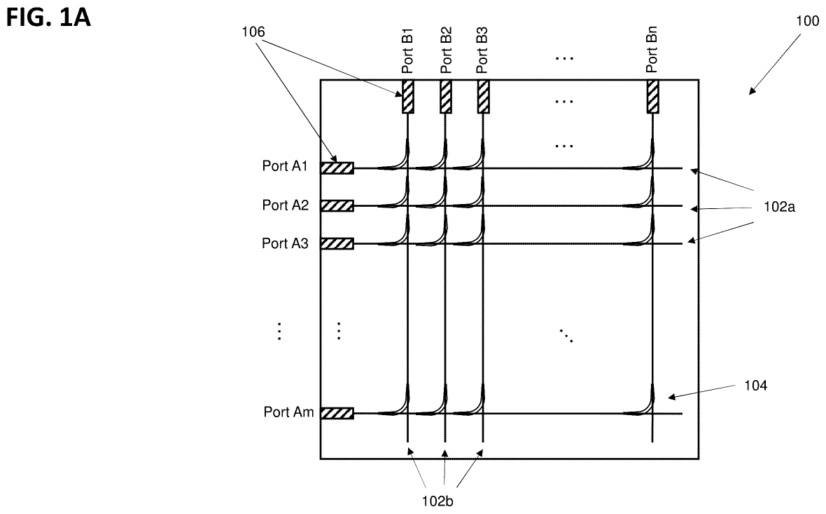

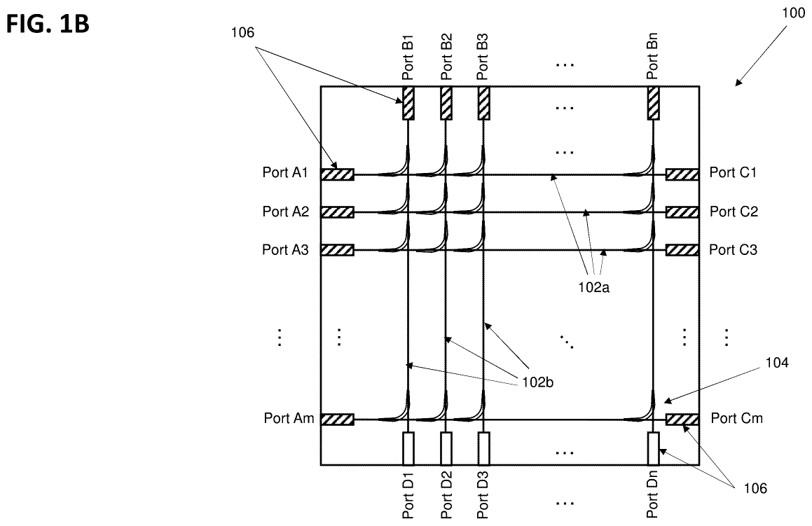

FIGS. 1A-1B show top-view schematics of an integrated MEMS optical circuit switch (OCS) 100 which includes a substrate with bus waveguides 102a/102b and switch unit cells 104 that include coupler waveguides and piezoelectric MEMS actuators configured to selectively couple light between one bus waveguide to another. In an embodiment shown in FIG. 1A, the OCS 100 has two sets of input/output ports, labeled “A1”, “A2”, . . . , “Am”, and “B1”, “B2”, . . . , “Bn”. In another embodiment shown in FIG. 1B, the OCS 100 has four sets of input/output ports, labeled “A1”, “A2”, . . . , “Am”, “B1”, “B2”, . . . , “Bn”, “C1”, “C2”, . . . , “Cm”, and “D1”, “D2”, . . . , “Dn”. They are sometimes referred to as “input”, “output” or “drop”, “through”, and “add” ports, respectively. However, the ports may be used in either input or output direction, or they may be bi-directional. Fiber couplers 106 are used to couple light between external optical fibers and the integrated OCS 100.

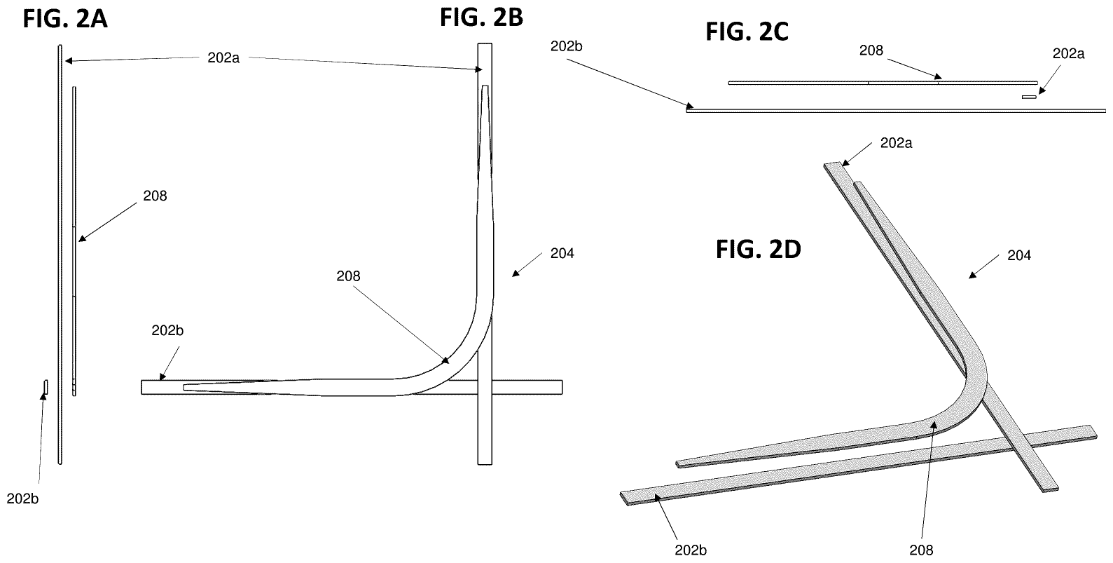

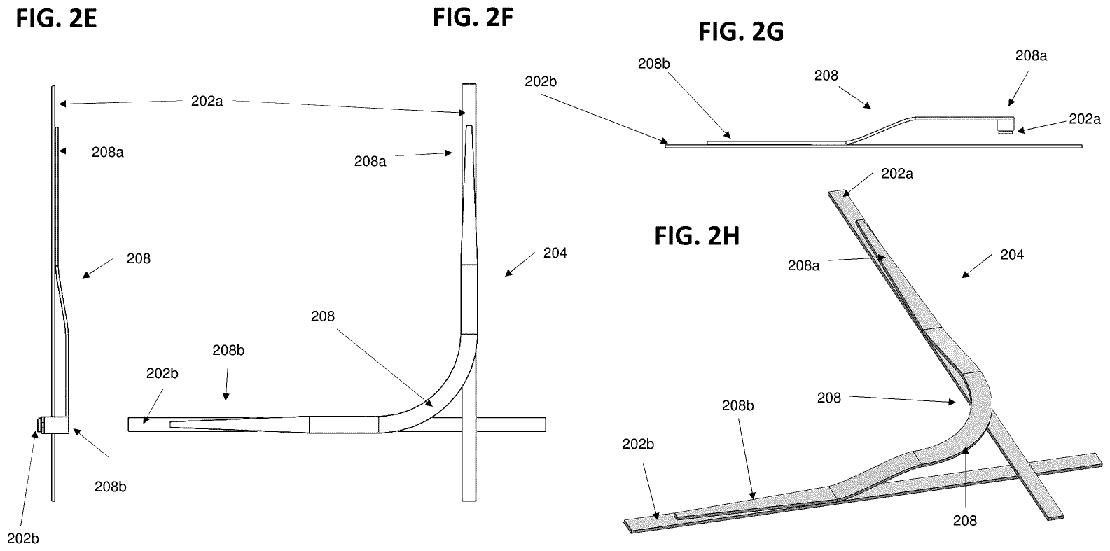

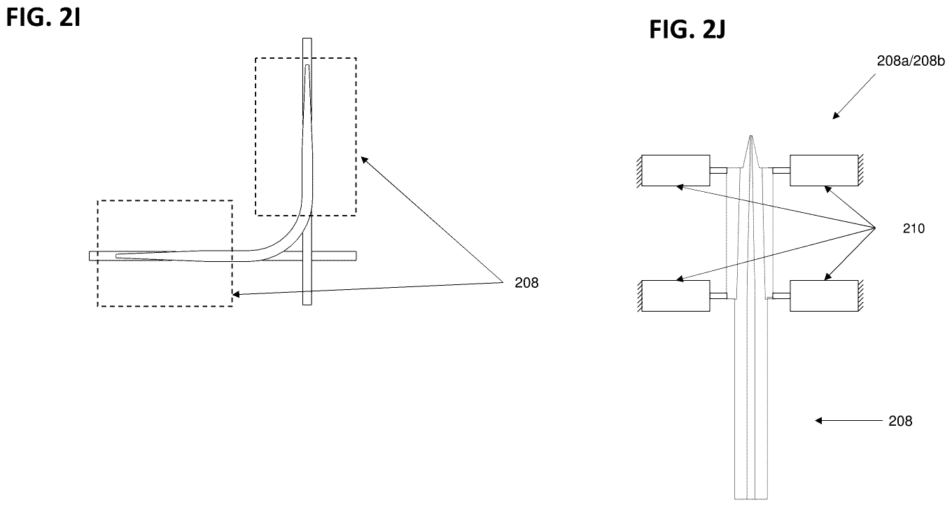

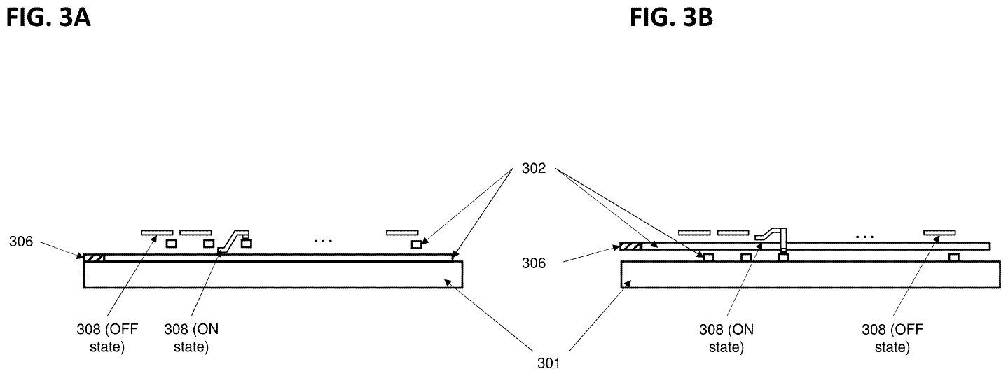

Each port is connected to a corresponding bus waveguide. In each switch unit cell 104, a coupler waveguide with piezoelectric MEMS actuators is located on each cross point of the bus waveguides. Note that the bus waveguides 102(a) and 102(b) may not physically cross each other but are in different planes or substrate layers as better shown in, for example, FIG. 2G and FIGS. 3A and 3B. The “cross points” are where bus waveguides 102(a) and 102(b) cross in the top view.

FIGS. 2A-2H shows the structure of bus waveguides 202a/202b, switch cell units 204 including coupler waveguides 208 and piezoelectric MEMS actuators. In this embodiment, the bus waveguides in two directions (202a/202b) are located on different layers of the substrate, and the coupler waveguide 208 are located on a third layer in the substrate above the bus waveguides 202a/202b. In the “OFF” state (FIGS. 2A-2D), the coupler waveguide 208 is kept enough distance away from the bus waveguides, so that light propagating in the bus waveguides is not affected by the coupler waveguide. In the “ON” state (FIGS. 2E-2H), the two ends 208a/208b of the coupler waveguide 208 are moved toward the bus waveguide layers 202a/202b by the piezoelectric MEMS actuators, so that light propagating in one of the two bus waveguides is optically coupled into the coupler waveguide and then optically coupled into the other bus waveguide.

FIGS. 2I-2J show an example of a coupler waveguide 208 with piezoelectric MEMS actuators 210, where two pairs of piezoelectric MEMS actuators drive each end 208a of the coupler waveguide. A different number of piezoelectric MEMS actuators may be used in other embodiments.

In one embodiment, the coupler waveguide ends are tapered (as shown in FIGS. 2A-2J) to improve the coupling efficiency. Other coupler waveguide and MEMS actuator designs are also possible.

The MEMS OCS with piezoelectric MEMS actuators of the present disclosure may be fabricated by a single-wafer or a two-wafer process. FIGS. 3A-3B show front and side view schematics using a single-wafer process. The two layers of bus waveguides 302 are first fabricated on a silicon or a silicon-on-insulator (SOI) substrate 301 using standard silicon photonics fabrication processes. Either silicon or silicon nitride bus waveguides can be used. Then the coupler waveguide 308 and piezoelectric actuators are fabricated on a third layer on top of the bus waveguide layers. Coupler waveguide ends are shown in FIGS. 3A-3B in both the ON and OFF states. Fiber couplers 306 are also shown.

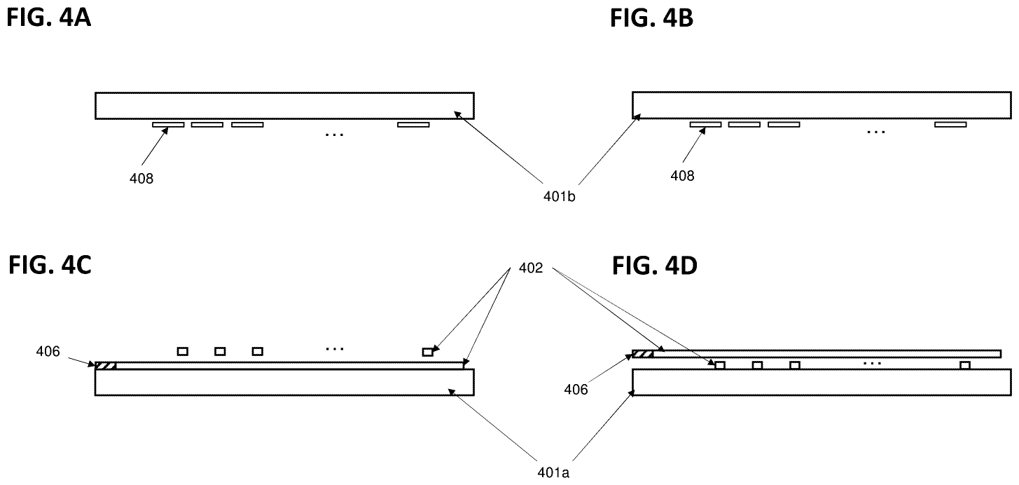

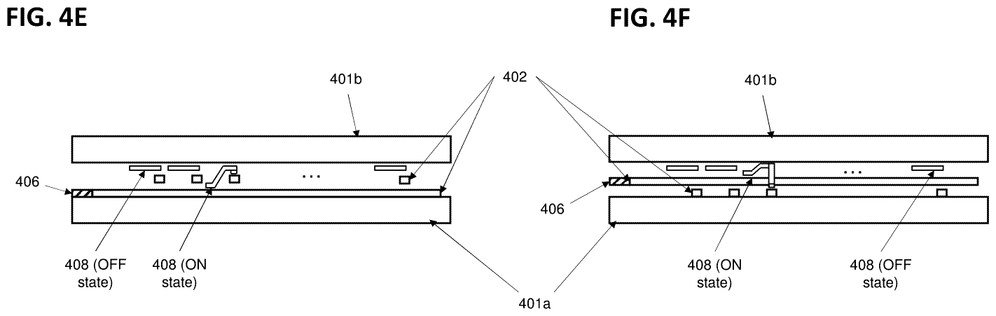

FIGS. 4A-4F show front and side view schematics using a two-wafer process. in FIGS. 4C-4D, the two layers of bus waveguides 402 are first fabricated on a silicon or a silicon-on-insulator (SOI) substrate 401a using standard silicon photonics fabrication processes. Either silicon or silicon nitride bus waveguides can be used. Fiber couplers 406 can also be fabricated on the wafer 401a.

In FIGS. 4A-4B, the coupler waveguide 408 and piezoelectric actuators are fabricated on another substrate 401b. Complementary metal-oxide-semiconductor (CMOS) driver circuits may be fabricated on wafer 401b for electrical control of the MEMS actuators before the fabrication of the coupler waveguide and piezoelectric actuators. In one embodiment, the two fabricated wafers are aligned and assembled first, then diced to singulate the OCS devices. In another embodiment, the two fabricated wafers are diced first, and the dies from two wafers are aligned and assembled to form an OCS device.

FIGS. 4E-4F show front and side views of the OCS device of FIGS. 4A-4D after bonding wafers 401a and 401b together. The end portions of coupler waveguides 308 are shown in FIGS. 4E-4F in both the ON and OFF states. Fiber couplers 406 are also shown.

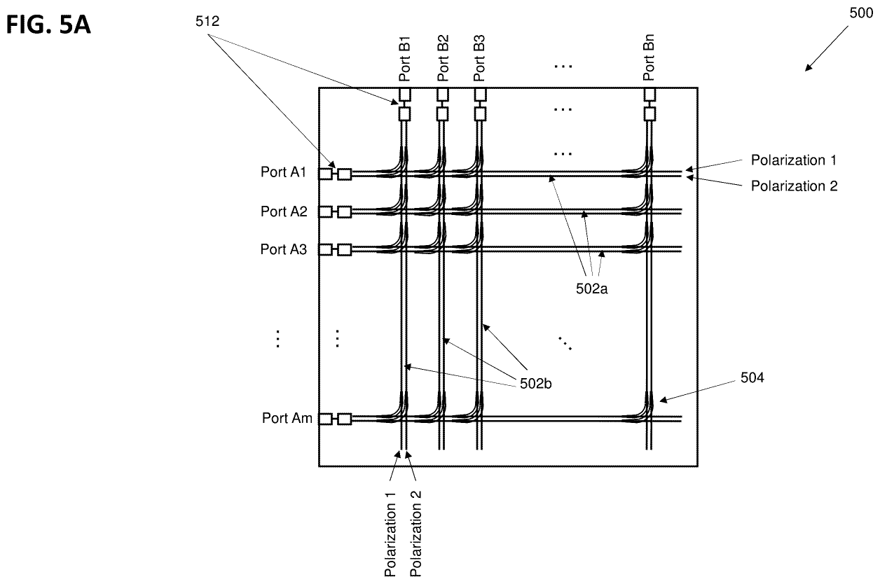

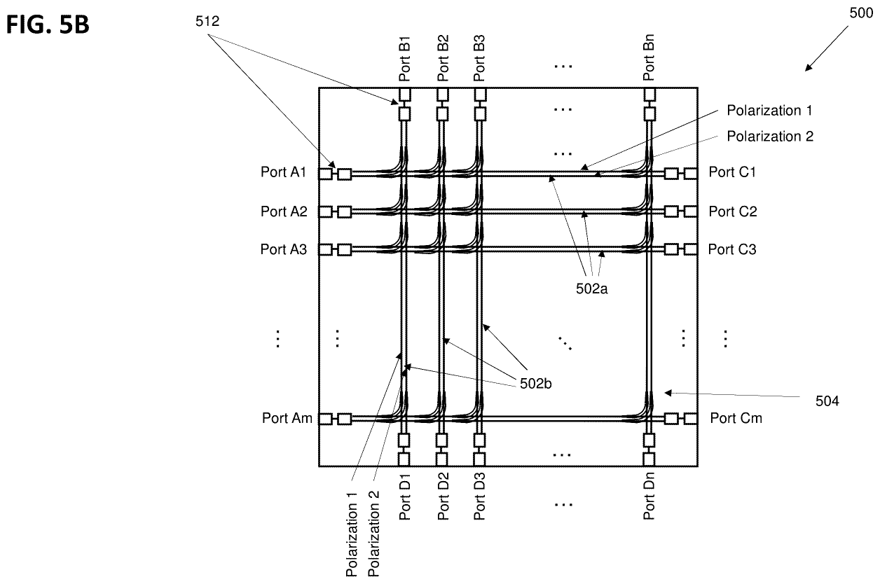

FIGS. 5A-5B show top-view schematics of a polarization diverse integrated MEMS OCS 500 with switch unit cells 504 that include coupler waveguides and piezoelectric MEMS actuators. In an embodiment shown in FIG. 5A, the OCS 500 has two sets of input/output ports, labeled “A1”, “A2”, . . . , “Am”, and “B1”, “B2”, . . . , “Bn”. In another embodiment shown in FIG. 5(b), the OCS has four sets of input/output ports, labeled “A1”, “A2”, . . . , “Am”, “B1”, “B2”, . . . , “Bn”, “C1”, “C2”, . . . , “Cm”, and “D1”, “D2”, . . . , “Dn”. They are sometimes referred to as “input”, “output” or “drop”, “through”, and “add” ports, respectively. However, the ports may be used in either input or output direction, or they may be bi-directional. Fiber couplers are used to couple light between external optical fibers and the integrated OCS device.

Each port of the OCS is connected to a pair of corresponding bus waveguides (502a/502b) via a polarization splitter-rotator (PSR) 512. In contrast to the waveguides discussed above, in which, for example, each waveguide 102a/102b/202a/202b/302/402 comprised a single waveguide, the waveguides 502a/502b of the present embodiment each include a pair of waveguides. In each switch unit cell 504, a pair of coupler waveguides with piezoelectric MEMS actuators is located on each cross point of the bus waveguide pairs. As noted in connection with the discussion of FIG. 1, the bus waveguides may not physically cross each other, and the “cross points” are where they cross in the top view.

In one embodiment, when light is coupled into the OCS 500, the PSR 512 splits the input light into TE and TM polarization components. The TE polarization component of light is sent into one bus waveguide (labeled “polarization 1” in FIGS. 5A-5B) in the bus waveguide pair, and the TM polarization component of light is rotated into TE polarization and sent into the other bus waveguide (labeled “polarization 2” in FIGS. 5A-5B) in the bus waveguide pair. When light is coupled out from the OCS, light in the “polarization 2” bus waveguide is rotated into TM polarization by the PSR 512, and then combined with light in the “polarization 1” bus waveguide with TE polarization. The combined light is coupled out of the OCS 500.

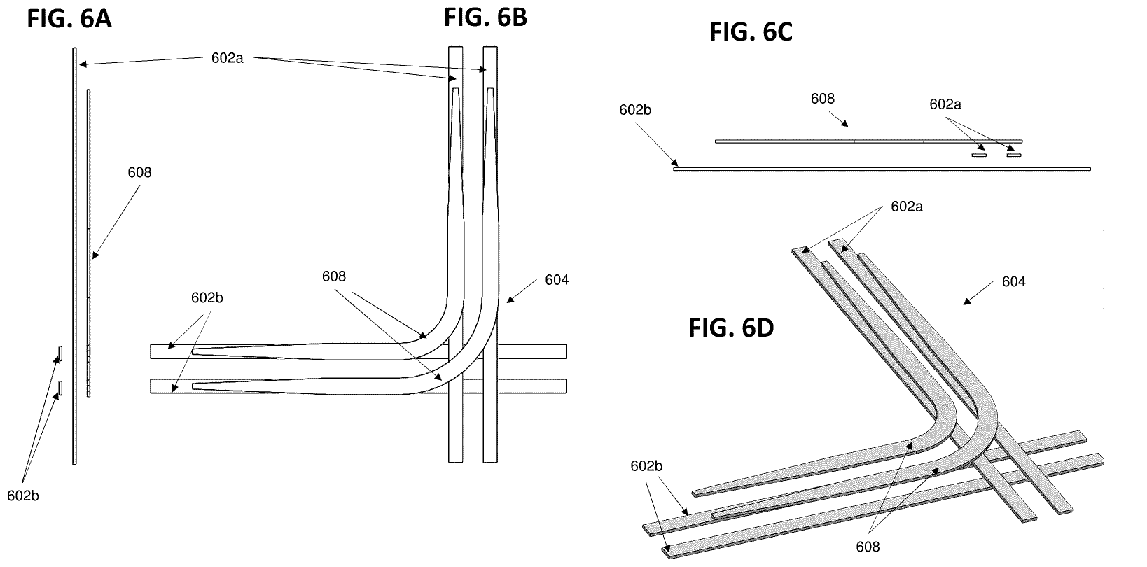

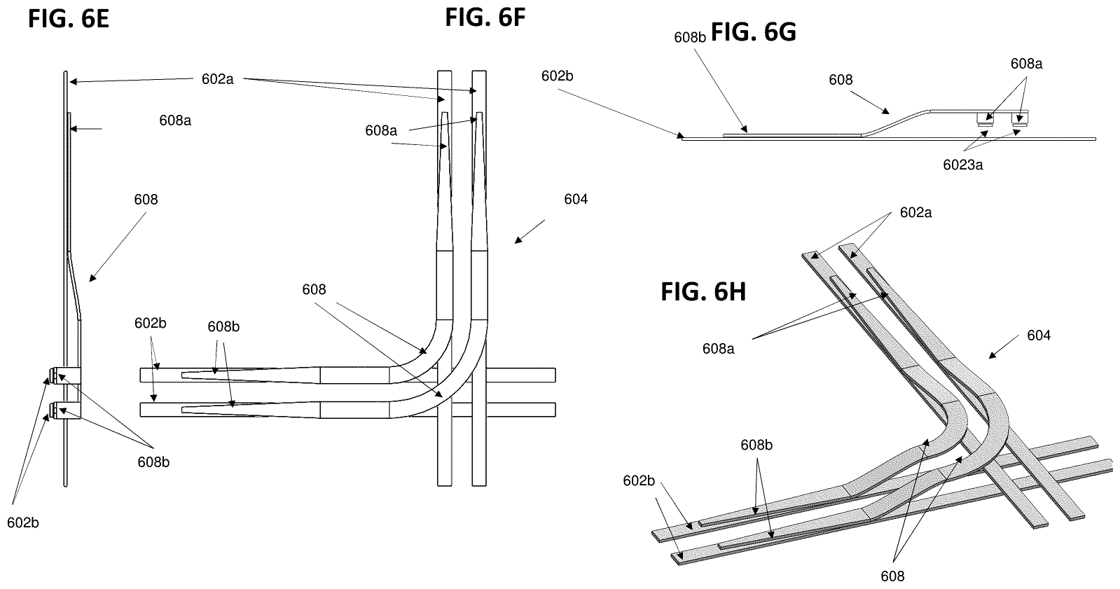

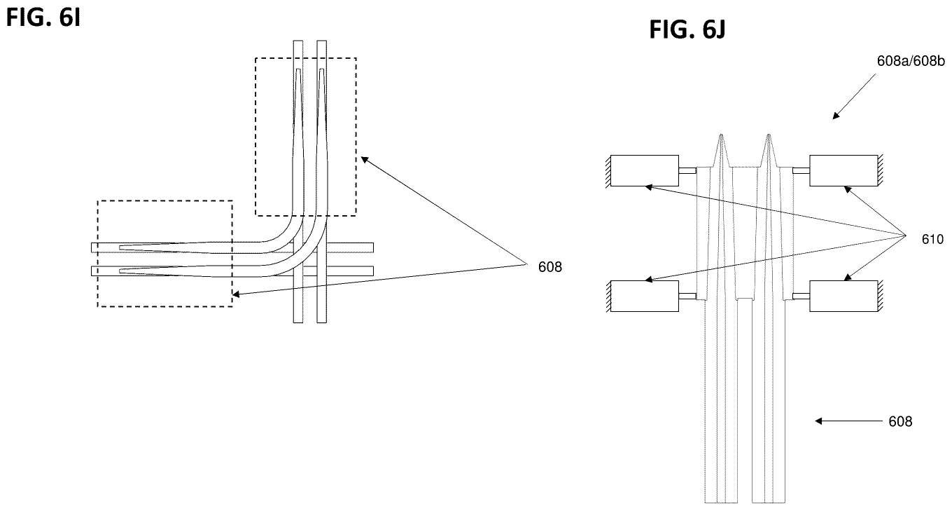

FIGS. 6A-6H show the structure of bus waveguides 602a/602b, switch cell units 604 including coupler waveguides 608 and piezoelectric MEMS actuators in one unit cell, corresponding to the pairs of waveguides, coupler waveguides, and MEMS actuators in FIGS. 5A-5B. In this embodiment, the bus waveguide pairs in two directions are located on different layers, and the coupler waveguides are located on a third layer above the bus waveguides. In the “OFF” state (FIGS. 6A-6D), the coupler waveguides 608 are kept enough distance away from the bus waveguides, so that light propagating in the bus waveguides is not affected by the coupler waveguides. In the “ON” state (FIGS. 6E-6H), the two ends 608a/608b of the coupler waveguides 608 are moved toward the bus waveguide layers by the piezoelectric MEMS actuators, so that light propagating in one of the two bus waveguide pairs is optically coupled into the coupler waveguides and then optically coupled into the other bus waveguide pair.

FIGS. 6I-6J show an example of coupler waveguides with piezoelectric MEMS actuators 610, where two pairs of piezoelectric MEMS actuators drive each end of the coupler waveguides. A different number of piezoelectric MEMS actuators may be used in other embodiments.

In one embodiment, the coupler waveguide ends are tapered (as shown in FIGS. 6A-6J) to improve the coupling efficiency. Other coupler waveguide and MEMS actuator designs are also possible.

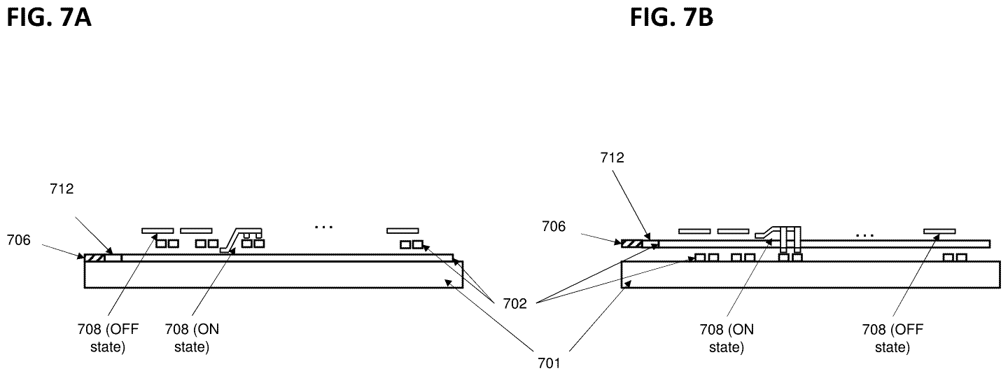

The polarization diverse MEMS OCS with piezoelectric MEMS actuators of the present disclosure may be fabricated by a single-wafer or a two-wafer process. FIGS. 7A-7B shows front and side view schematics using a single-wafer process. The two layers of bus waveguides 702 are first fabricated on a silicon or a silicon-on-insulator (SOI) substrate 701 using standard silicon photonics fabrication processes. Either silicon or silicon nitride bus waveguides can be used. Then the coupler waveguides 708 and piezoelectric actuators are fabricated on a third layer on top of the bus waveguide layers. Coupler waveguide ends are shown in FIGS. 7A-7B in both the ON and OFF states. Fiber couplers 706 and PSR 712 are also shown.

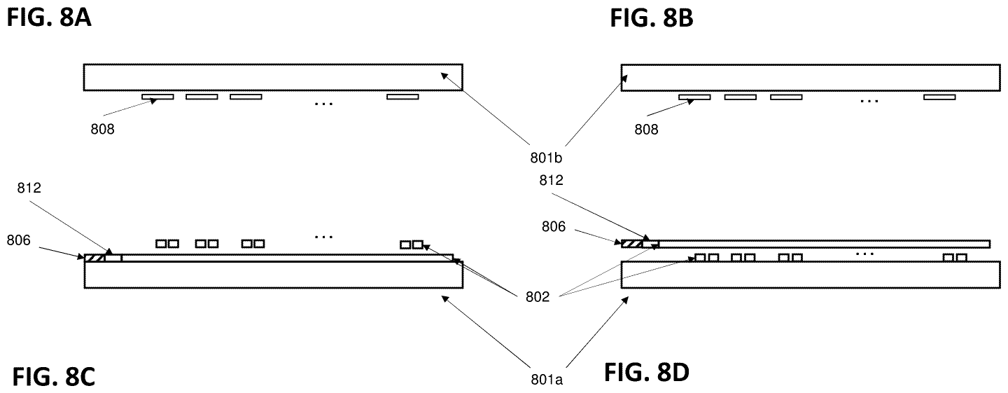

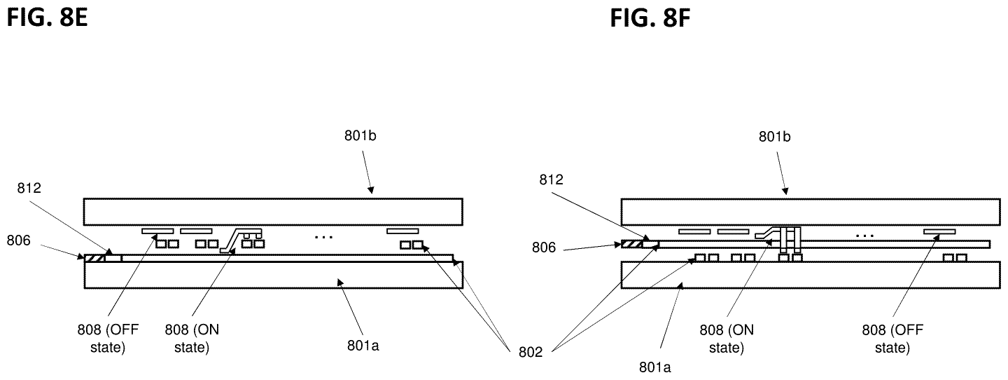

FIGS. 8A-8F show front and side view schematics using a two-wafer process. In FIGS. 8C-8D, the two layers of bus waveguides 802 are first fabricated on a silicon or a silicon-on-insulator (SOI) substrate 801a using standard silicon photonics fabrication processes. Either silicon or silicon nitride bus waveguides can be used. Fiber couplers 806 and PSR 812 can also be fabricated on the wafer 401a.

In FIGS. 8A-8B, the coupler waveguides 808 and piezoelectric actuators are fabricated on another substrate 801b. CMOS driver circuits may be fabricated on wafer 801b for electrical control of the MEMS actuators before the fabrication of the coupler waveguides and piezoelectric actuators. In one embodiment, the two fabricated wafers are aligned and assembled first, then diced to singulate the OCS devices. In another embodiment, the two fabricated wafers are diced first, and the dies from two wafers are aligned and assembled to form an OCS device.

FIGS. 8E-8F show front and side views of the OCS device of FIGS. 8A-8D after bonding wafers 801a and 801b together. Coupler waveguide ends are shown in FIGS. 8E-8F in both the ON and OFF states. Fiber couplers 806 and PSR 812 are also shown.

In any of the piezoelectric MEMS actuator embodiments described herein, a layer (or two layers) of piezoelectric material can be deposited on one side (or both sides) of the structural material of the coupler waveguide (for example, silicon). When a voltage is applied to the piezoelectric material, an internal mechanical strain in the piezoelectric material will be generated from the electric field, therefore bending the actuator and the coupler waveguide or coupler waveguide end. Two-directional actuation can be achieved by depositing piezoelectric materials on both sides of the structural material of the coupler waveguide, or by pre-biasing a single-side piezoelectric actuator.

In “OFF” state of the MEMS actuator, the coupler waveguide is kept enough distance away from the bus waveguides, so that light propagating in the bus waveguides is not affected by the coupler waveguide. In “ON” state of the MEMS actuator, the two ends of the coupler waveguide are moved toward the bus waveguide layers by the piezoelectric MEMS actuators, so that light propagating in one of the two bus waveguides is optically coupled into the coupler waveguide and then optically coupled into the other bus waveguide.

By selectively turning on some of the MEMS actuators, a one-to-one optical connection map between the port set “A” and “B” can be established, and the connection configuration can be changed as desired by controlling the ON and OFF states of the MEMS actuators.

Piezoelectric MEMS actuators have advantages over other actuators in the art, including low actuation voltage, low power consumption, large actuation and restoring forces, large displacement, and two-directional actuation.

As for additional details pertinent to the present invention, materials and manufacturing techniques may be employed as within the level of those with skill in the relevant art. The same may hold true with respect to method-based aspects of the invention in terms of additional acts commonly or logically employed. Also, it is contemplated that any optional feature of the inventive variations described may be set forth and claimed independently, or in combination with any one or more of the features described herein. Likewise, reference to a singular item, includes the possibility that there are plural of the same items present. More specifically, as used herein and in the appended claims, the singular forms “a,” “and,” “said,” and “the” include plural referents unless the context clearly dictates otherwise. It is further noted that the claims may be drafted to exclude any optional element. As such, this statement is intended to serve as antecedent basis for use of such exclusive terminology as “solely,” “only” and the like in connection with the recitation of claim elements, or use of a “negative” limitation. Unless defined otherwise herein, all technical and scientific terms used herein have the same meaning as commonly understood by one of ordinary skill in the art to which this invention belongs. The breadth of the present invention is not to be limited by the subject specification, but rather only by the plain meaning of the claim terms employed.

What is claimed is:

1. A photonic integrated circuit (PIC) device, comprising:
a substrate;
one or more rows of horizontal waveguides disposed on a first layer of the substrate;
one or more columns of vertical waveguides disposed on a second layer of the substrate;
one or more fiber couplers configured to couple external light to the one or more rows of horizontal waveguides or columns of vertical waveguides; and
a matrix of photonic switches arranged at intersections between the one or more rows of horizontal waveguides and the one or more rows of vertical waveguides, the photonic switches including piezoelectric actuators that are selectively actuated to transfer light from the first and second horizontal waveguides for a selected row of horizontal waveguides to first and second vertical waveguides of an intersecting column of vertical waveguides.

2. The PIC of claim 1, wherein each photonic switch comprises a coupler waveguide, wherein the piezoelectric actuators are disposed on the coupler waveguide.

3. The PIC of claim 2, wherein the piezoelectric actuators are disposed on a first surface of the coupler waveguide.

4. The PIC of claim 2, wherein the piezoelectric actuators are disposed on first and second surfaces of the coupler waveguide.

5. The PIC of claim 2, wherein the coupler waveguide comprises a silicon material.

6. The PIC of claim 2, wherein application of voltage to the piezoelectric actuators induces an internal mechanical strain in the piezoelectric actuators to bend the coupler waveguide.

7. The PIC of claim 2, wherein the photonic switches each comprise an OFF state in which the coupler waveguide is maintained at a distance away from the one or more rows of horizontal waveguides or vertical waveguides such that light propagating in the one or more rows of horizontal waveguides or vertical waveguides is not affected by the coupler waveguides.

8. The PIC of claim 2, wherein the photonic switches each comprise an OFF state in which ends of the coupler waveguides are moved towards the one or more rows of horizontal waveguides or vertical waveguides to optically couple the one or more rows of horizontal waveguides or vertical waveguides to the coupler waveguides.

9. The PIC of claim 1, wherein the PIC is fabricated on a silicon-on-insulator (SOI) substrate.

10. The PIC of claim 9, wherein the one or more rows of horizontal waveguides and one or more rows of vertical waveguides are disposed on first and second layers of the SOI substrate.

11. The PIC of claim 10, wherein the matrix of photonic switches are fabricated on a third layer of the SOI substrate.

12. The PIC of claim 11, wherein the third layer is above the first and second layers.

13. The PIC of claim 1, wherein the one or more rows of horizontal waveguides and one or more rows of vertical waveguides are disposed on a first substrate, and the matrix of photonic switches are fabricated on a second substrate.

14. The PIC of claim 13, further comprising complementary metal-oxide-semiconductor (CMOS) driver circuits disposed on the second substrate and configured to control actuation of the matrix of photonic switches.

15. A photonic integrated circuit (PIC) device, comprising:
a substrate;
one or more rows of horizontal waveguides disposed on a first layer of the substrate, each row of horizontal waveguides comprising a first horizontal waveguide and a second horizontal waveguide;
one or more columns of vertical waveguides disposed on a second layer of the substrate, each column of vertical waveguides comprising a first vertical waveguide and a second vertical waveguide;
one or more fiber couplers configured to couple external light to the one or more rows of horizontal waveguides or columns of vertical waveguides;
an input polarization splitter rotator (PSR) coupled to each of the one or more fiber couplers, each input PSR being configured to split the coupled light into the first and second horizontal waveguides in each of the one or more rows of horizontal waveguides or into the first and second vertical waveguides in each of the one or more columns of vertical waveguides; and
a matrix of photonic switches arranged at intersections between the one or more rows of horizontal waveguides and the one or more rows of vertical waveguides, the photonic switches including piezoelectric actuators that are selectively actuated to transfer light from the first and second horizontal waveguides for a given row of horizontal waveguides to first and second vertical waveguides of an intersecting column of vertical waveguides.

16. The PIC of claim 15, wherein each photonic switch comprises a coupler waveguide, wherein the piezoelectric actuators are disposed on the coupler waveguide.

17. The PIC of claim 16, wherein the piezoelectric actuators are disposed on a first surface of the coupler waveguide.

18. The PIC of claim 16, wherein the piezoelectric actuators are disposed on first and second surfaces of the coupler waveguide.

19. The PIC of claim 16, wherein the coupler waveguide comprises a silicon material.

20. The PIC of claim 16, wherein application of voltage to the piezoelectric actuators induces an internal mechanical strain in the piezoelectric actuators to bend the coupler waveguide.

21. The PIC of claim 16, wherein the photonic switches each comprise an OFF state in which the coupler waveguide is maintained at a distance away from the one or more rows of horizontal waveguides or vertical waveguides such that light propagating in the one or more rows of horizontal waveguides or vertical waveguides is not affected by the coupler waveguides.

22. The PIC of claim 16, wherein the photonic switches each comprise an OFF state in which ends of the coupler waveguides are moved towards the one or more rows of horizontal waveguides or vertical waveguides to optically couple the one or more rows of horizontal waveguides or vertical waveguides to the coupler waveguides.

23. The PIC of claim 15, wherein the PIC is fabricated on a silicon-on-insulator (SOI) substrate.

24. The PIC of claim 23, wherein the one or more rows of horizontal waveguides and one or more rows of vertical waveguides are disposed on first and second layers of the SOI substrate.

25. The PIC of claim 24, wherein the matrix of photonic switches are fabricated on a third layer of the SOI substrate.

26. The PIC of claim 25, wherein the third layer is above the first and second layers.

27. The PIC of claim 15, wherein the one or more rows of horizontal waveguides and one or more rows of vertical waveguides are disposed on a first substrate, and the matrix of photonic switches are fabricated on a second substrate.

28. The PIC of claim 27, further comprising complementary metal-oxide-semiconductor (CMOS) driver circuits disposed on the second substrate and configured to control actuation of the matrix of photonic switches.

29. The PIC device of claim 15, further comprising an output PSR coupled to each of the one or more columns of vertical waveguides, each output PSR being configured to combine the light from the first and second vertical waveguides into a single output waveguide.

30. The PIC device of claim 16, further comprising one or more output polarization-insensitive couplers coupled to each output waveguide.

31. The PIC device of claim 15, wherein the input PSRs are configured to split the input light into two orthogonal polarizations in two separate waveguides and rotate a polarization of one of the two separate waveguides to achieve the same polarization in the two separate waveguides.

32. The PIC device of claim 15, wherein the polarization-diverse photonic switches are micro-electro-mechanical-system (MEMS) switches.
